(19) United States
(12) Patent Application Publication
(10) Pub. No.: US 2024/0369640 A1
(43) Pub. Date: Nov. 7, 2024

(54) BATTERY MANAGEMENT SYSTEM, BATTERY MANAGEMENT METHOD, AND BATTERY MANAGEMENT PROGRAM

(71) Applicant: Energywith Co., Ltd., Tokyo (JP)

(72) Inventors: Akihiko KUDO, Tokyo (JP); Koji HAYATA, Tokyo (JP); Hideharu OOMIZU, Tokyo (JP)

(21) Appl. No.: 18/563,228

(22) PCT Filed: May 25, 2022
(86) PCT No.: PCT/JP2022/021367

§ 371 Date: Nov. 21, 2023

(30) Foreign Application Priority Data
May 28, 2021 (JP) 2021-090522
May 28, 2021 (JP) 2021-090528

(51) Int. Cl. G01R 31/3842; B60L 58/12; B60L 58/16; G01R 31/379; G01R 31/389; G01R 31/392; H01M 10/06; H01M 10/42; H01M 10/48

(52) U.S. Cl. CPC G01R 31/3842; B60L 58/12; B60L 58/16; G01R 31/379; G01R 31/389; G01R 31/392; H01M 10/06; H01M 10/425; H01M 10/48; H01M 2010/4271; H01M 2220/20

(57) ABSTRACT

A battery management system according to one aspect includes: an acquisition unit configured to acquire reference data indicating a state of a rechargeable battery in a reference period and target data indicating a state of the rechargeable battery in a target period that is after the reference period; a characteristic calculation unit configured to calculate a characteristic value corresponding to a state of charge of the rechargeable battery in the reference period as a reference characteristic value based on the reference data, and calculate a characteristic value corresponding to a state of charge of the rechargeable battery in the target period as a target characteristic value based on the target data; and a ratio calculation unit configured to calculate a ratio indicating a relationship between the reference characteristic value and the target characteristic value, as a reference value for predicting a lifespan of the rechargeable battery.

### TECHNICAL FIELD

One aspect of the present disclosure relates to a battery management system, a battery management method, and a battery management program.

### BACKGROUND ART

Patent Literature 1 describes a state monitoring system for a lead-acid battery. This system includes a device for measuring an internal resistance of the lead-acid battery, a device for calculating an average of the internal resistance for each predetermined period, comparing the average of the internal resistance for each predetermined period with an average for an immediately preceding predetermined period, and calculating a change rate between the average values, and a device for alarming or displaying a replacement timing of the lead-acid battery in a case where the change rate exceeds a prescribed value.

### CITATION LIST

### Patent Literature

[Patent Literature 1] JP 4353653 B

### SUMMARY OF INVENTION

### Technical Problem

In one aspect of the present disclosure, an effective index for predicting a lifespan of a rechargeable battery is desired.

### Solution to Problem

A battery management system according to an aspect of the present disclosure includes: an acquisition unit configured to acquire reference data indicating a state of a rechargeable battery in a reference period and target data indicating a state of the rechargeable battery in a target period that is after the reference period; a characteristic calculation unit configured to calculate a characteristic value corresponding to a state of charge of the rechargeable battery in the reference period as a reference characteristic value based on the reference data, and calculate a characteristic value corresponding to a state of charge of the rechargeable battery in the target period as a target characteristic value based on the target data; and a ratio calculation unit configured to calculate a ratio indicating a relationship between the reference characteristic value and the target characteristic value, as a reference value for predicting a lifespan of the rechargeable battery.

A battery management method according to an aspect of the present disclosure is executed by a battery management system including at least one processor. The battery management method includes: acquiring reference data indicating a state of a rechargeable battery in a reference period and target data indicating a state of the rechargeable battery in a target period that is after the reference period; calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and calculating a ratio indicating a relationship between the reference characteristic value and the target characteristic value, as a reference value for predicting a lifespan of the rechargeable battery.

A battery management program according to an aspect of the present disclosure causes a computer to execute: acquiring reference data indicating a state of a rechargeable battery in a reference period and target data indicating a state of the rechargeable battery in a target period that is after the reference period; calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and calculating a ratio indicating a relationship between the reference characteristic value and the target characteristic value, as a reference value for predicting a lifespan of the rechargeable battery.

In such aspects, a degree of change in the characteristic value corresponding to the state of charge of the rechargeable battery over time from the reference period to the target period is obtained as the reference value. This reference value makes it possible to predict how the characteristics of the rechargeable battery will change further in the future. Therefore, it can be said that the reference value is an effective index for predicting a lifespan of the rechargeable battery.

### Advantageous Effects of Invention

According to one aspect of the present disclosure, it is possible to obtain an effective index for predicting a lifespan of a rechargeable battery.

### BRIEF DESCRIPTION OF DRAWINGS

FIG. 1 is a diagram showing an example functional configuration of a battery management system.

FIG. 2 is a diagram showing an example hardware configuration of a computer constituting the battery management system.

FIG. 3 is a flowchart showing an example of processing by the battery management system.

FIG. 4 is a diagram showing an example graph relating to reference characteristic values and target characteristic values.

FIG. 5 is a diagram showing another example of the functional configuration of the battery management system.

FIG. 6 is a flowchart showing another example of processing by the battery management system.

FIG. 7 is a flowchart showing an example of predicting battery life based on a characteristic value corresponding to an SOC.

FIG. 8 is a diagram showing an example report.

### DESCRIPTION OF EMBODIMENTS

Hereinafter, embodiments of the present disclosure will be described in detail with reference to the accompanying drawings. In the description of the drawings, the same or equivalent elements are denoted by the same reference signs, and redundant description is omitted.

### First Example

### (Configuration of System)

A battery management system according to the present disclosure is a computer system that calculates a reference value for predicting a lifespan of a rechargeable battery (secondary battery). The reference value may be used as an effective index for predicting the lifespan of the rechargeable battery. Examples of types of rechargeable batteries include, but are not limited to, a lead-acid battery and a lithium-ion battery. The rechargeable battery may be an assembled battery composed of a plurality of single batteries of the same type. In one example, a battery management system 1 predicts a lifetime of a rechargeable battery installed in a control system such as a device, equipment, and a movable object. For example, the rechargeable battery may be mounted on an electric vehicle. An electric vehicle refers to a vehicle that travels using electrical energy stored in a rechargeable battery as all or part of power. The electric vehicle may be a vehicle for carrying a person or a vehicle for moving a cargo. The electric vehicle may be a material handling vehicle for moving a cargo, for example a forklift. In one example, the battery management system 1 may calculate the reference value for predicting the lifespan of the lead-acid battery mounted on the material handling vehicle. Alternatively, the rechargeable battery may be installed in a power generation facility using renewable energy, such as a solar power plant, a wind power plant, etc.

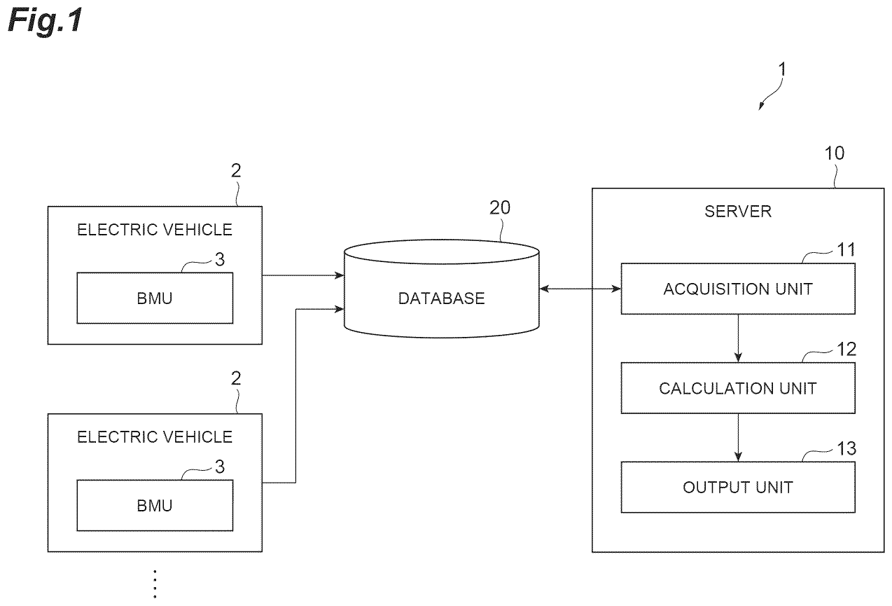

FIG. 1 is a diagram showing a functional configuration of the battery management system 1 according to an example. The battery management system 1 calculates the reference value for predicting the lifespan of the rechargeable battery mounted on an electric vehicle 2. In one example, the battery management system 1 includes a server 10. The server 10 may access, via a communication network, a database 20 that stores rechargeable battery data indicating a state of the rechargeable battery mounted on the electric vehicle 2. The database 20 stores the rechargeable battery data for each of at least one electric vehicle 2. The database 20 may be a component of the battery management system 1 or may be provided in a computer system separate from the battery management system 1. The communication network used for the battery management system 1 is constituted by, for example, at least one of the Internet and an intranet.

The individual electric vehicle 2 provides the rechargeable battery data to the database 20. The electric vehicle 2 includes a battery management unit (BMU) 3 that monitors or controls the rechargeable battery. The BMU 3 repeatedly measures the state of the rechargeable battery at given time intervals and generates the rechargeable battery data indicative of that state. The BMU 3 then transmits the rechargeable battery data to the database 20 via the communication network at a given timing. The rechargeable battery data is time-series data indicating the state of the rechargeable battery. For example, each record of the rechargeable battery data includes a measurement date and time and at least one physical quantity indicating the state of the rechargeable battery. Examples of the physical quantity include, but are not limited to, a measured voltage, a measured current, and a measured temperature. The rechargeable battery data indicates physical quantities measured every 100 milliseconds, for example. In the database 20, the rechargeable battery data is associated with at least one of a rechargeable battery ID and an electric vehicle ID. The rechargeable battery ID is an identifier that uniquely identifies a rechargeable battery. The electric vehicle ID is an identifier that uniquely identifies the electric vehicle 2.

The server 10 is a computer that calculates the reference value based on the rechargeable battery data. The server 10 includes an acquisition unit 11, a calculation unit 12, and an output unit 13 as functional modules. The acquisition unit 11 is a functional module that acquires the rechargeable battery data from the database 20. The calculation unit 12 is a functional module that calculates the reference value based on the rechargeable battery data. The output unit 13 is a functional module that outputs the reference value.

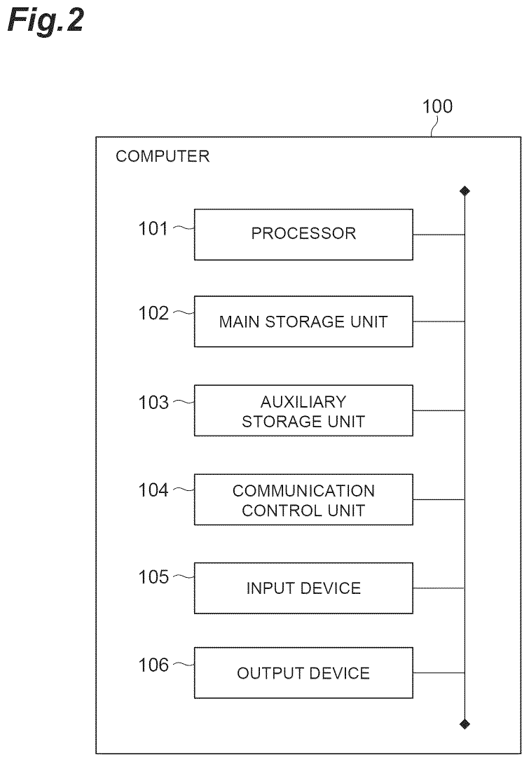

FIG. 2 is a diagram showing an example of a general hardware configuration of a computer 100 constituting the server 10. For example, the computer 100 includes a processor (for example, a CPU) 101 that executes an operating system, an application program, and the like, a main storage unit 102 constituted by a ROM and a RAM, an auxiliary storage unit 103 constituted by a storage device such as a hard disk or a flash memory, a communication control unit 104 constituted by a network card or a wireless communication module, an input device 105 such as a keyboard or a mouse, and an output device 106 such as a monitor.

Each functional module of the server 10 is implemented by reading a predetermined program on a processor 101 or the main storage unit 102 and causing the processor 101 to execute the program. The processor 101 operates the communication control unit 104, the input device 105, or the output device 106 according to the program to read and write data in the main storage unit 102 or the auxiliary storage unit 103. The data or database required for processing is stored in the main storage unit 102 or the auxiliary storage unit 103.

The server 10 is constituted by at least one computer. In a case where a plurality of computers is used, these computers are connected via a communication network such as the Internet or an intranet, whereby one logical the server 10 is constructed.

### (Calculation Theory of Reference Value)

In one example, the calculation unit 12 calculates the characteristic value corresponding to a state of charge (SOC) of the rechargeable battery for each of a reference period and a target period that is after the reference period. Thus, the calculation unit 12 functions as a characteristic calculation unit. In the present disclosure, a characteristic value in the reference period is also referred to as a “reference characteristic value”, and a characteristic value in the target period is also referred to as a “target characteristic value”. These characteristic values are not the SOC itself but are values obtained based on the SOC.

In one example, each of the reference period and the target period is a time width from when charging of the rechargeable battery is completed to when next charging is started. In this case, the SOC at the start point is 100% in both the reference period and the target period.

In one example, the calculation unit 12 may calculate a parameter obtained from a relationship between the SOC and an open-circuit voltage (OCV), as the characteristic value. In the present disclosure, this parameter is also referred to as an “OCV-SOC parameter”. Alternatively, the calculation unit 12 may calculate a parameter obtained from a relationship between the SOC and a DC-resistance (DCR), as the characteristic value. In the present disclosure, this parameter is also referred to as a “DCR-SOC parameter”. In these examples, the calculation unit 12 performs a calculation based on an equivalent circuit of the rechargeable battery. The equivalent circuit includes a power source whose voltage changes in proportion to the SOC and an internal resistor whose resistance changes in proportion to the SOC. The calculation based on the equivalent circuit includes a linear equation (1) indicating an OCV-SOC characteristic that is a relationship between the SOC and the OCV, and a linear equation (2) indicating a DCR-SOC characteristic that is a relationship between the SOC and the DCR. In these two equations, a denotes an intercept and b denotes a slope. It can be said that all of a_{OCV}, b_{OCV}, a_{DCR}, and b_{DCR} are first-order approximation constants.

$$OCV = {a}_{OCV} + {b}_{OCV} \cdot SOC \qquad ( 1 )$$

$$DCR = {a}_{DCR} + {b}_{DCR} \cdot SOC \qquad ( 2 )$$

The calculation unit 12 may obtain the b_{OCV} in Equation (1) as the characteristic value. The constant b_{OCV} is an example of the OCV-SOC parameter. The calculation unit 12 may obtain DCR when the SOC is 50%, which is obtained from Equation (2), as the characteristic value. In the present disclosure, the DCR when the SOC is 50% is also referred to as DCR₅₀. The DCR₅₀ is an example of the DCR-SOC parameter.

The calculation unit 12 calculates a ratio indicating a relationship between a reference characteristic value and a target characteristic value as the reference value. Therefore, the calculation unit 12 also functions as a ratio calculation unit. The reference value indicates how the characteristics of the rechargeable battery change over time from the reference period to the target period. The reference value may represent a state of health (SOH) of the rechargeable battery. By using this reference value, it may be expected to predict the lifespan of the rechargeable battery.

### (Operation of System)

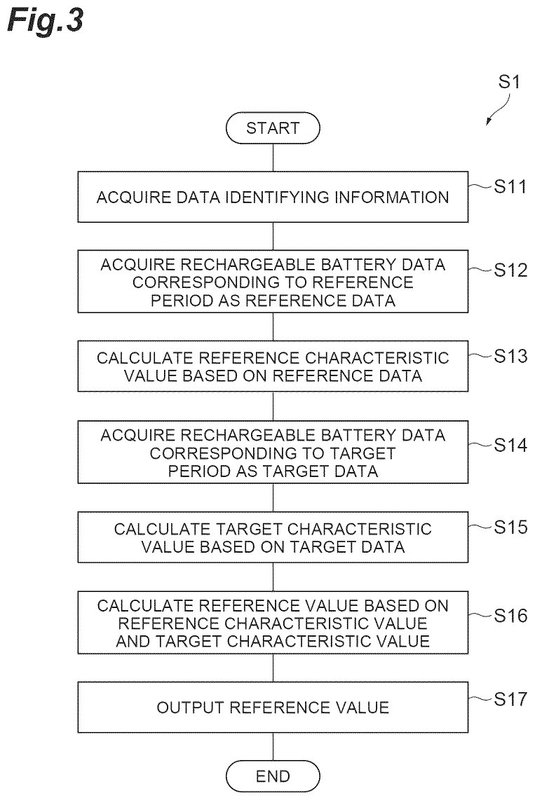

With reference to FIG. 3, an example of processing by the battery management system 1 (server 10) will be described, and an example of the battery management method according to the present embodiment will be described. FIG. 3 is a flowchart showing an example of processing as a processing flow S1. The processing flow S1 represents the process of calculating the reference value for a certain rechargeable battery (electric vehicle 2). The server 10 may perform the processing flow S1 for each of a plurality of rechargeable batteries (electric vehicles 2).

In step S11, the acquisition unit 11 acquires data identifying information. The data identifying information refers to information used to read the rechargeable battery data from the database 20. In one example, the data identifying information includes at least one of the rechargeable battery ID and the electric vehicle ID, the reference period, and the target period. For example, the reference period may correspond to a time when the rechargeable battery is new, and the target period may correspond to a past time including a current time. The acquisition unit 11 may receive the data identifying information input by a user of the battery management system 1, or may automatically set the data identifying information based on a given rule.

In step S12, the acquisition unit 11 acquires the rechargeable battery data corresponding to the reference period as reference data. The acquisition unit 11 reads out records of the rechargeable battery data corresponding to at least one of the rechargeable battery ID and the electric vehicle ID and the reference period, from the database 20.

In step S13, the calculation unit 12 calculates the reference characteristic value based on the reference data. In one example, the calculation unit 12 calculates moving averages of the measured voltage and the measured current, for each of a plurality of intervals set along a time axis. For example, in a case where the time interval between records is 100 milliseconds, the calculation unit 12 sets the interval to 10 seconds and calculates an average of 100 physical quantities in that interval every 10 seconds. Further, the calculation unit 12 calculates the SOC for each interval. Subsequently, the calculation unit 12 selects a set of intervals in which the moving average of the measured current is greater than or equal to a given threshold. This threshold may be a value for distinguishing whether or not the electric vehicle 2 is in an idling state. The calculation unit 12 then calculates an I-V characteristic in the reference period by a statistical approach based on data of the selected set of intervals, and obtains the reference characteristic value based on the I-V characteristic. In the present disclosure, the I-V characteristic refers to a relationship of the measured current, the measured voltage, and the SOC. In the present disclosure, the “data of the selected set of intervals” is also referred to as “partial data”.

In a case where the measured voltage at the time of a small current is used, a calculation error of the OCV and therefore a calculation error of the characteristic value become large. Further, depending on a current sensor, an offset error due to temperature and a hysteresis error due to residual magnetism become large at the time of a small current, which increases an error in calculation of the SOC. By excluding intervals corresponding to the idling state in which the current is small, these errors may be reduced or avoided, and the characteristic value may be accurately calculated. The idling state refers to a state in which the electric vehicle 2 is in operation with no load.

The threshold for distinguishing whether the electric vehicle 2 is in the idling state may be a threshold caused by the offset error of the current sensor, and may be set to 1 (A), for example. In this case, the error of the SOC may be reduced. Alternatively, the threshold for distinguishing whether the electric vehicle 2 is in the idling state may be a threshold caused by battery characteristics, and may be set to 0.05, for example. In this case, the I-V characteristic may be obtained more accurately.

The calculation unit 12 calculates the SOC (k) for each interval k in which the moving average is obtained, by Equation (3).

$$SOC ( k ) = [ {W}_{bat} - Σ \{ I ( k ) / α \} ] / {W}_{bat} \qquad ( 3 )$$

The W_{bat} denotes a rated capacity of the rechargeable battery, and the I(k) denotes the measured current in the interval k. The α is a coefficient for converting the current (A) into the capacity (Ah). If the interval length is 10 seconds, then α=360. Σ{I(k)/α} indicates a consumption capacity of the rechargeable battery up to the interval k.

As a result, the calculation unit 12 obtains the measured current I(k), the measured voltage MV(k), and the SOC(k) for each of n intervals k (k=1 to n). That is, the calculation unit 12 obtains time-series data for the moving average of the current, the moving average of the measured voltage, and the corresponding SOC.

Subsequently, the calculation unit 12 calculates the first-order approximation constants a_{OCV}, b_{OCV}, a_{DCR} and b_{DCR} in Equations (1) and (2), based on the n sets of the measured current, the measured voltage, and the SOC, by a statistical approach. As an example, the calculation unit 12 may use the Marquardt method, which is a nonlinear least square method, as the statistical approach. The calculation unit 12 uses the Marquardt method to calculate the first-order approximation constants a_{OCV}, b_{OCV}, a_{DCR} and b_{DCR} that minimize the mean square error between the measured voltage MV and a theoretical voltage CV. In one example, the theoretical voltage CV(k) at an interval k is given by Equation (4). Equation (4) may represent the I-V characteristic of the rechargeable battery based on the equivalent circuit of the rechargeable battery, and may be an equation of the theoretical voltage.

$$CV ( k ) = OCV ( k ) - I ( k ) \cdot DCR ( k ) = \{ {a}_{OCV} + {b}_{OCV} \cdot SOC ( k ) \} - I ( k ) \cdot \{ {a}_{DCR} + {b}_{DCR} \cdot SOC ( k ) \} \qquad ( 4 )$$

Alternatively, the calculation unit 12 may use a multivariate analysis as the statistical approach. In one example, the calculation unit 12 may calculate the first-order approximation constants a_{OCV}, b_{OCV}, a_{DCR} and b_{DCR} based on Equation (4).

That is, the calculation unit 12 calculates the I-V characteristic using the statistical approach such as the Marquardt method and the multivariate analysis, so that the mean square error between the measured voltage MV and the theoretical voltage CV is minimized, and calculates the first-order approximation constants a_{OCV}, b_{OCV}, a_{DCR} and b_{DCR} obtained from the I-V characteristic.

In one example, the calculation unit 12 obtains at least one of b_{OCV} and DCR₅₀ as the reference characteristic value.

In step S14, the acquisition unit 11 acquires the rechargeable battery data corresponding to the target period as target data. The acquisition unit 11 reads out records of the rechargeable battery data corresponding to at least one of the rechargeable battery ID and the electric vehicle ID and the target period, from the database 20.

In step S15, the calculation unit 12 calculates the target characteristic value based on the target data. In one example, the calculation unit 12 calculates the target characteristic value in a manner similar to the reference characteristic value. That is, the calculation unit 12 calculates moving averages of the measured voltage and the measured current for each predetermined interval. Further, the calculation unit 12 calculates the SOC for each interval. Subsequently, the calculation unit 12 selects a set of intervals in which the moving average of the measured current is greater than or equal to a given threshold. The calculation unit 12 then calculates the I-V characteristic in the target period by a statistical approach, based on data of the selected set of intervals, that is, the partial data, and obtains the target characteristic value based on the I-V characteristic. The interval for calculating the moving average and the threshold for selecting the interval are the same as those in the case of calculating the reference characteristic value. In one example, the calculation unit 12 calculates the I-V characteristic using the Marquardt method or the multivariate analysis so that the mean square error between the measured voltage MV and the theoretical voltage CV is minimized, and calculates first-order approximation constants a_{OCV}, b_{OCV}, a_{DCR}, and b_{DCR} obtained from the I-V characteristic.

In step S16, the calculation unit 12 calculates the reference value based on the reference characteristic value and the target characteristic value. The calculation unit 12 calculates a ratio indicating a relationship between the reference characteristic value and the target characteristic value as the reference value. The calculation unit 12 calculates at least one reference value.

The calculation unit 12 may calculate a ratio related to the OCV-SOC parameter as the reference value. In one example, the calculation unit 12 calculates a ratio indicating a relationship between the b_{OCV} in the reference period and the b_{OCV} in the target period as the reference value. The calculation unit 12 may calculate a ratio of an inverse number of the b_{OCV} in the target period to an inverse number of the b_{OCV} in the reference period as the reference value. In the present disclosure, this reference value is also referred to as “SOH-Q”. The inverse number of b_{OCV} is also expressed as b_{OCV}⁻¹.

The calculation unit 12 may calculate a ratio related to the DCR-SOC parameter as the reference value. In one example, the calculation unit 12 may calculate a ratio of the DCR₅₀ in the target period to the DCR₅₀ in the reference period as the reference value. In the present disclosure, this reference value is also referred to as “SOH-R”.

In step S17, the output unit 13 outputs the reference value. This reference value may be used to predict the lifespan of the rechargeable battery. The output unit 13 may output at least one reference value to another functional module in the battery management system 1 for subsequent processing in the battery management system 1.

Alternatively, the output unit 13 may store the at least one reference value in a predetermined storage device, such as memory and database. Alternatively, the output unit 13 may display the at least one reference value on a display device. Alternatively, the output unit 13 may transmit the at least one reference value to another computer system.

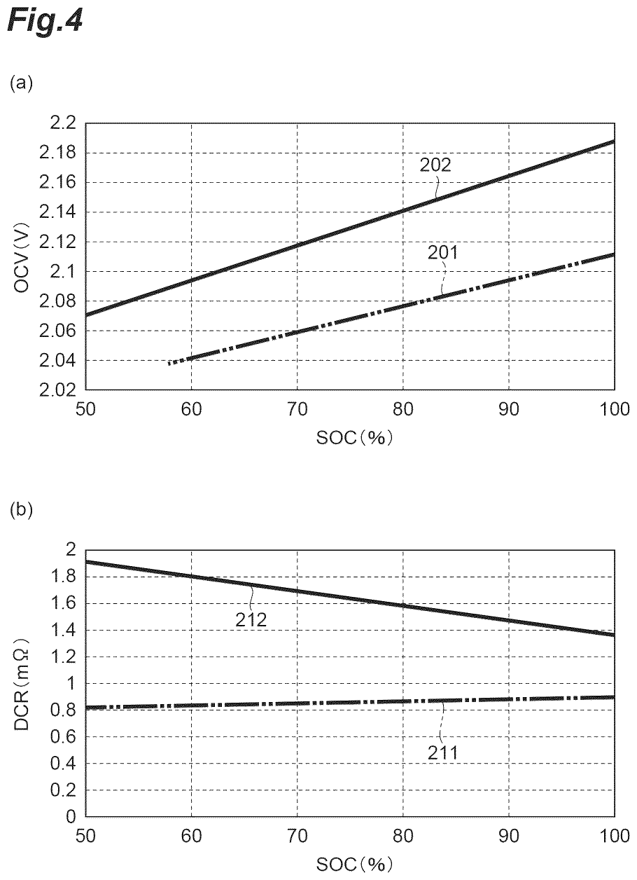

With reference to FIG. 4, the SOH-Q and SOH-R, which are examples of the reference value, will be described. FIG. 4 is a diagram showing an example graph relating to the reference characteristic value and the target characteristic value.

Example (a) shows the OCV-SOC characteristic represented by the above linear equation (1). The horizontal axis represents SOC (%), and the vertical axis represents OCV (V). Graphs 201 and 202 both represent the OCV-SOC characteristic represented by the above linear equation (1). The graph 201 represents the OCV-SOC characteristic in the reference period, and the graph 202 represents the OCV-SOC characteristic in the target period. In this example, the reference period corresponds to a time when the rechargeable battery is new, and the target period corresponds to a time when the rechargeable battery has deteriorated. As may be seen from the graphs 201 and 202, as the rechargeable battery deteriorates, the characteristic value b_{OCV} indicating the slope of the graph increases and the inverse number b_{OCV}⁻¹ decreases. Therefore, the reference value SOH-Q gradually decreases from 100% (or 1.0) as the rechargeable battery deteriorates. Since a decrease in the inverse number b_{OCV}⁻¹ means a decrease in the capacity of the rechargeable battery, a decrease in the reference value SOH-Q indicates a decrease in the capacity of the rechargeable battery.

Example (b) shows the DCR-SOC characteristic shown in linear equation (2) above. The horizontal axis represents SOC (%), and the vertical axis represents DCR (mΩ). Graphs 211 and 212 both represent the DCR-SOC characteristic represented by the above linear equation (2). The graph 211 indicates the DCR-SOC characteristic in the reference period and the graph 212 indicates the DCR-SOC characteristic in the target period. Also in this example, the reference period corresponds to a time when the rechargeable battery is new, and the target period corresponds to a time when the rechargeable battery has deteriorated. As may be seen from the graphs 211 and 212, the characteristic value DCR₅₀ increases as the rechargeable battery degrades. Therefore, the reference value SOH-R gradually increases from 100% (or 1.0) as the rechargeable battery deteriorates.

### (Program)

A battery management program for causing a computer or computer system to function as the battery management system 1 or the server 10 includes a program code for causing the computer or computer system to function as the acquisition unit 11, the calculation unit 12, and the output unit 13. The battery management program may be provided after being non-temporarily recorded in a tangible recording medium such as a CD-ROM, a DVD-ROM, or a semiconductor memory. Alternatively, the battery management program may be provided as a data signal superimposed on a carrier through a communication network. The provided battery management program may be stored in the auxiliary storage unit 103, for example. The processor 101 reads and executes the battery management program from the auxiliary storage unit 103 to implement the functional modules described above.

### Second Example

### (Configuration of System)

In one aspect of the present disclosure, it is desirable to convey a future state of a rechargeable battery mounted on an electric vehicle to a user. A battery management system according to this aspect is a computer system that predicts a future state of a rechargeable battery (secondary battery) and provides a user with a report indicating the prediction result. In one example, the battery management system predicts a future state of the rechargeable battery installed in a control system such as a device, equipment, and a movable object, and provides the report indicating the prediction result. For example, the rechargeable battery may be mounted on an electric vehicle. In an example, the battery management system may provide the user with the report indicating the prediction result related to a lead-acid battery mounted on a material handling vehicle.

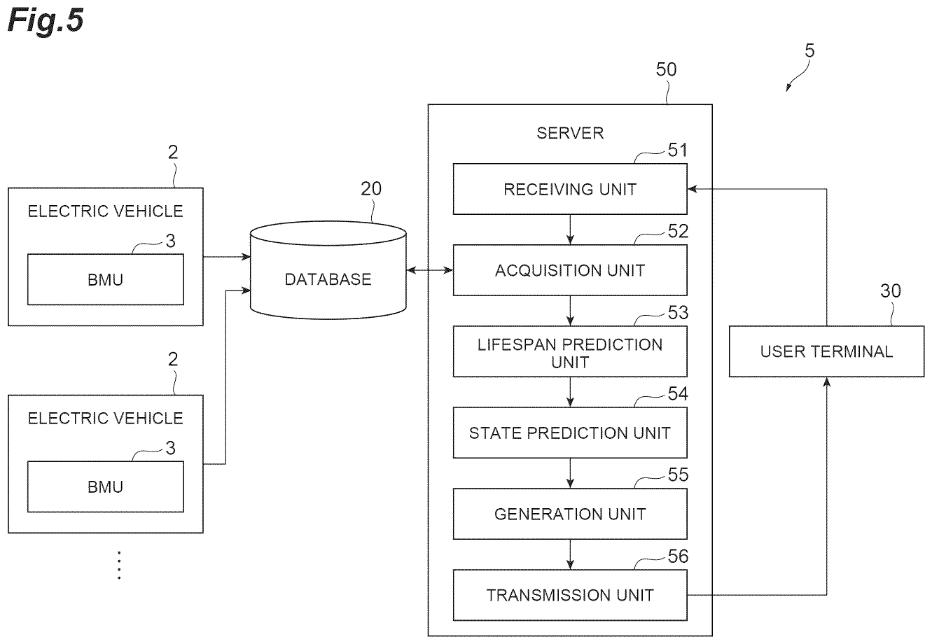

FIG. 5 is a diagram showing a functional configuration of a battery management system 5 according to an example. The battery management system 5 predicts a future state of the rechargeable battery mounted on the electric vehicle 2 and provides a report indicating the prediction result to the user. In one example, the battery management system 5 includes a server 50. The server 50 may access the database 20 above via a communication network. The database 20 may be a component of the battery management system 5 or may be provided in a computer system separate from the battery management system 5. The server 50 is further connected to at least one user terminal 30 via a communication network. The communication network used for the battery management system 5 is constituted by, for example, at least one of the Internet and an intranet.

The server 50 is a computer that predicts a future state of the rechargeable battery based on rechargeable battery data and provides a report indicating the prediction result to the user. The server 50 includes a receiving unit 51, an acquisition unit 52, a lifespan prediction unit 53, a state prediction unit 54, a generation unit 55, and a transmission unit 56 as functional modules. The receiving unit 51 is a functional module that receives a request to generate and provide a report, from the user terminal 30. The acquisition unit 52 is a functional module that acquires the rechargeable battery data from the database 20 based on the request. The lifespan prediction unit 53 is a functional module that predicts the lifespan of the rechargeable battery based on the rechargeable battery data. In the present disclosure, the lifespan of a rechargeable battery is also referred to as “battery life”. The state prediction unit 54 is a functional module that predicts the temporal change in a state of the rechargeable battery in the future based on the battery life. The generation unit 55 is a functional module that generates a report indicating the temporal change. The transmission unit 56 is a functional module that transmits the report to the user terminal 30. This transmission is an example of the output of the report, and thus the transmission unit 56 functions as an output unit.

The user terminal 30 is a computer operated by the user of the battery management system 5. Examples of the user include, but are not limited to, a sales representative responsible for selling rechargeable batteries, a service worker performing maintenance on rechargeable batteries, and an owner or administrator of the electric vehicle 2.

### (Operation of System)

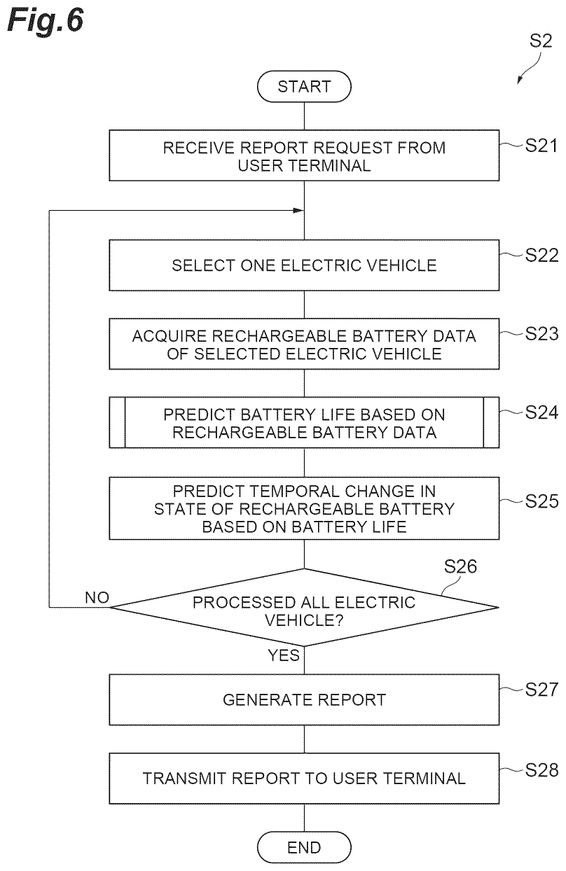

With reference to FIG. 6, an example of processing by the battery management system 5 (the server 50) will be described, and an example of the battery management method according to the present embodiment will be described. FIG. 6 is a flowchart showing the example of the processing as a processing flow S2.

In step S21, the receiving unit 51 receives a report request from the user terminal 30. The report request is a data signal for requesting the server 50 to generate and provide a report. The user terminal 30 generates the report request based on a user operation and transmits the report request to the server 50. In one example, the report request includes at least one electric vehicle ID, for example, the electric vehicle ID of at least one electric vehicle 2 located at a particular location such as a business office and a work-site.

In step S22, the acquisition unit 52 selects one electric vehicle 2 (one electric vehicle ID) based on the report request.

In step S23, the acquisition unit 52 acquires the rechargeable battery data of the selected electric vehicle 2. The acquisition unit 52 reads out the rechargeable battery data corresponding to the selected electric vehicle ID from the database 20. In a case where the rechargeable battery ID is used, the lifespan prediction unit 53 refers to given data indicating correspondence between the electric vehicle ID and the rechargeable battery ID to identify the rechargeable battery ID from the electric vehicle ID, and reads out the rechargeable battery data corresponding to the rechargeable battery ID from the database 20.

In step S24, the lifespan prediction unit 53 predicts the battery life of the selected electric vehicle 2 based on the rechargeable battery data. The lifespan prediction unit 53 may calculate an operating rate of the electric vehicle 2 or a discharge capacity per unit time from the rechargeable battery data and predict the battery life based on the operating rate or discharge capacity. Alternatively, the lifespan prediction unit 53 may predict the battery life based on a characteristic value corresponding to a state of charge (SOC) of the rechargeable battery.

As an example of step S24, a process of predicting the battery life based on the characteristic value corresponding to the SOC will be described below.

The lifespan prediction unit 53 obtains the characteristic value corresponding to the SOC for each of a reference period and a target period that is after the reference period. Therefore, the lifespan prediction unit 53 also functions as a characteristic calculation unit.

In one example, the lifespan prediction unit 53 may calculate an OCV-SOC parameter obtained from a relationship between the SOC and an open-circuit voltage (OCV), as the characteristic value. Alternatively, the lifespan prediction unit 53 may calculate a DCR-SOC parameter obtained from a relationship between the SOC and a DC resistance (DCR), as the characteristic value. In these examples, the lifespan prediction unit 53 executes a calculation that is based on the equivalent circuit of the rechargeable battery and includes Equations (1) and (2) above. The lifespan prediction unit 53 may obtain the b_{OCV} in Equation (1) or the DCR₅₀ calculated from Equation (2) as the characteristic value.

The lifespan prediction unit 53 calculates a ratio indicating a relationship between a reference characteristic value and a target characteristic value as the reference value. Therefore, the lifespan prediction unit 53 also functions as a ratio calculation unit. The lifespan prediction unit 53 predicts the battery life based on the reference value.

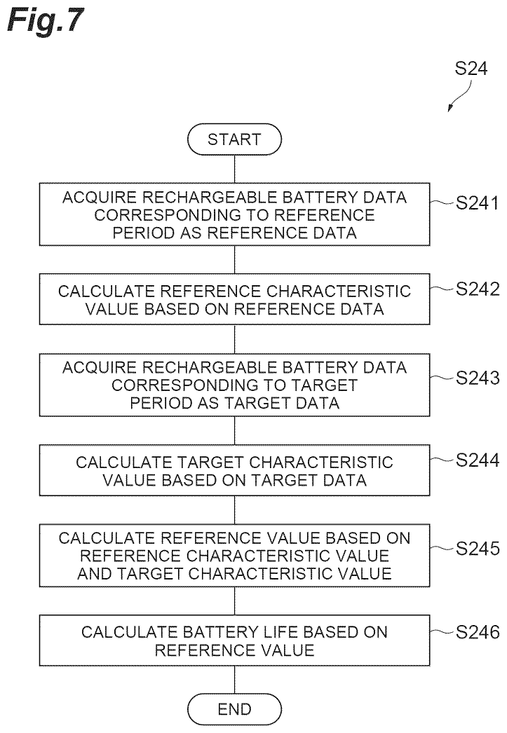

The prediction of the battery life based on the characteristic value corresponding to the SOC will be described in more detail with reference to FIG. 7. FIG. 7 is a flowchart showing an example prediction process. This flowchart shows the details of step S24.

In step S241, the lifespan prediction unit 53 acquires the rechargeable battery data corresponding to the reference period as reference data. In one example, the reference period corresponds to a time when the rechargeable battery is new. The lifespan prediction unit 53 selects records of the rechargeable battery data corresponding to the reference period.

In step S242, the lifespan prediction unit 53 calculates the reference characteristic value based on the reference data. In one example, the lifespan prediction unit 53 calculates moving averages of the measured voltage and measured current for each of a plurality of intervals set along a time axis. For example, in a case where the time interval between records is 100 milliseconds, the lifespan prediction unit 53 sets the interval to 10 seconds and calculates an average of 100 physical quantities in the interval every 10 seconds. Further, the lifespan prediction unit 53 calculates the SOC for each interval. Subsequently, the lifespan prediction unit 53 selects a set of intervals in which the moving average of the measured current is greater than or equal to a given threshold. The threshold may be a value for distinguishing whether the electric vehicle 2 is in an idling state. The lifespan prediction unit 53 then calculates an I-V characteristic in the reference period by a statistical approach, based on data of the selected set of intervals, and obtains the reference characteristic value based on the I-V characteristic.

The lifespan prediction unit 53 calculates the SOC (k) by the above equation (3), for each interval k in which the moving average is obtained. As a result, the lifespan prediction unit 53 obtains the measured current I(k), the measured voltage MV(k), and the SOC(k) for each of n intervals k (k=1 to n). That is, the lifespan prediction unit 53 obtains time-series data for the moving average of the current, the moving average of the measured voltage, and the corresponding SOC.

Subsequently, the lifespan prediction unit 53 calculates, by statistical approach, the first-order approximation constants a_{OCV}, b_{OCV}, a_{DCR} and b_{DCR} in the above-described Equations (1) and (2) based on the n combinations of the measured current, measured voltage, and SOC. As an example, the lifespan prediction unit 53 may use the Marquardt method, which is a nonlinear least square method, as the statistical approach. The lifespan prediction unit 53 uses the Marquardt method to calculate the first-order approximation constants a_{OCV}, b_{OCV}, a_{DCR} and b_{DCR} that minimize the mean square error between the measured voltage MV and the theoretical voltage CV. In one example, the theoretical voltage CV(k) in the interval k is obtained by Equation (4) above.

Alternatively, the lifespan prediction unit 53 may use a multivariate analysis as the statistical approach. In one example, the lifespan prediction unit 53 may calculate the first-order approximation constants a_{OCV}, b_{OCV}, a_{DCR} and b_{DCR} based on Equation (4).

That is, the lifespan prediction unit 53 calculates the I-V characteristic using the statistical approach such as the Marquardt method and multivariate analysis, so that the mean square error between the measured voltage MV and the theoretical voltage CV is minimized, and calculates the first-order approximation constants a_{OCV}, b_{OCV}, a_{DCR} and b_{DCR} obtained from the I-V characteristic.

In one example, the lifespan prediction unit 53 obtains at least one of the b_{OCV} and DCR₅₀ as the reference characteristic value.

In step S243, the lifespan prediction unit 53 acquires the rechargeable battery data corresponding to the target period as target data. For example, the target period corresponds to a past period including a current time. The lifespan prediction unit 53 selects records of the rechargeable battery data corresponding to the target period.

In step S244, the lifespan prediction unit 53 calculates the target characteristic value based on the target data. In one example, the lifespan prediction unit 53 calculates the target characteristic value in a manner similar to the reference characteristic value. That is, the lifespan prediction unit 53 calculates moving averages of the measured voltage and the measured current for each predetermined interval. Further, the lifespan prediction unit 53 calculates the SOC for each section. Subsequently, the lifespan prediction unit 53 selects a set of intervals in which the moving average of the measured current is greater than or equal to a given threshold. The lifespan prediction unit 53 then calculates an I-V characteristic in the target period by the statistical approach based on data of the selected set of intervals, that is, partial data, and obtains the target characteristic value based on the I-V characteristic. The interval for calculating the moving average and the threshold for selecting that interval are the same as those in the case of calculating the reference characteristic value. In one example, the lifespan prediction unit 53 calculates the I-V characteristic using the Marquardt method or the multivariate analysis, so that the mean square error between the measured voltage MV and the theoretical voltage CV is minimized, and calculates first-order approximation constants a_{OCV}, b_{OCV}, a_{DCR} and b_{DCR} obtained from the I-V characteristic.

In step S245, the lifespan prediction unit 53 calculates the reference value based on the reference characteristic value and the target characteristic value. The lifespan prediction unit 53 calculates a ratio indicating a relationship between the reference characteristic value and the target characteristic value as the reference value. The lifespan prediction unit 53 calculates at least one reference value. The lifespan prediction unit 53 may obtain SOH-Q or SOH-R as the reference value.

In step S246, the lifespan prediction unit 53 predicts the battery life based on the reference value. For example, the lifespan prediction unit 53 may predict the battery life from the reference value based on a correspondence table or an equation indicating a relationship between the reference value and a usage period of the rechargeable battery. In a case where the SOH-Q is used as the reference value, the lifespan prediction unit 53 may determine the time when the SOH-Q reaches a given threshold between 50% and 80%, as the battery life. In a case where the SOH-R is used as the reference value, the lifespan prediction unit 53 may determine the time where the SOH-R reaches a given threshold between 200 and 300%, as the battery life. The lifespan prediction unit 53 may predict the battery life based on both the SOH-Q and SOH-R.

Returning to FIG. 6, in step S25, the state prediction unit 54 predicts a temporal change in the state of the rechargeable battery in the future based on the battery life. For example, the state prediction unit 54 may predict the temporal change using a plurality of classifications. The plurality of classifications may represent at least one of a normal period in which the rechargeable battery may be normally used, a recommended period of budget in which making a budget for replacing the rechargeable battery is recommended, a recommended period of replacement in which replacement of the rechargeable battery is recommended, and a lifespan reaching period in which a lifespan of the rechargeable battery expires. In a case where the plurality of classifications represents these four types of periods, the temporal change of the state of the rechargeable battery proceeds in the order of the normal period, the recommended period of budget, the recommended period of replacement, and the lifespan reaching period. The state prediction unit 54 may predict the temporal change in the state of the rechargeable battery based on a correspondence table or an equation indicating a relationship between a time until the battery life and each classification.

As shown in step S26, the server 50 repeats the processing of steps S22 to S25 until all the electric vehicle 2 indicated by the report request have been processed. In a case where the process is repeated, a next electric vehicle 2 is selected in step S22, and the temporal change of the state of the rechargeable battery in that electric vehicle 2 is predicted by a series of processes of steps S23 to S25.

In step S27, the generation unit 55 generates the report indicating the temporal change of individual rechargeable batteries. This report is electronic data that may be visualized. For example, the generation unit 55 may generate a report indicating the temporal change in the state of each rechargeable battery using four classifications corresponding to the normal period, recommended period of budget, recommended period of replacement, the lifespan reaching period.

In step S28, the transmission unit 56 transmits the report to the user terminal 30. The user terminal 30 receives and displays the report. In a case where the report is represented using four classifications corresponding to the normal period, recommended period of budget, recommended period of replacement, and lifespan reaching period, the user may obtain information useful for management of the rechargeable battery, such as a timing of replacing the rechargeable battery and a timing of budgeting the replacement, through the report.

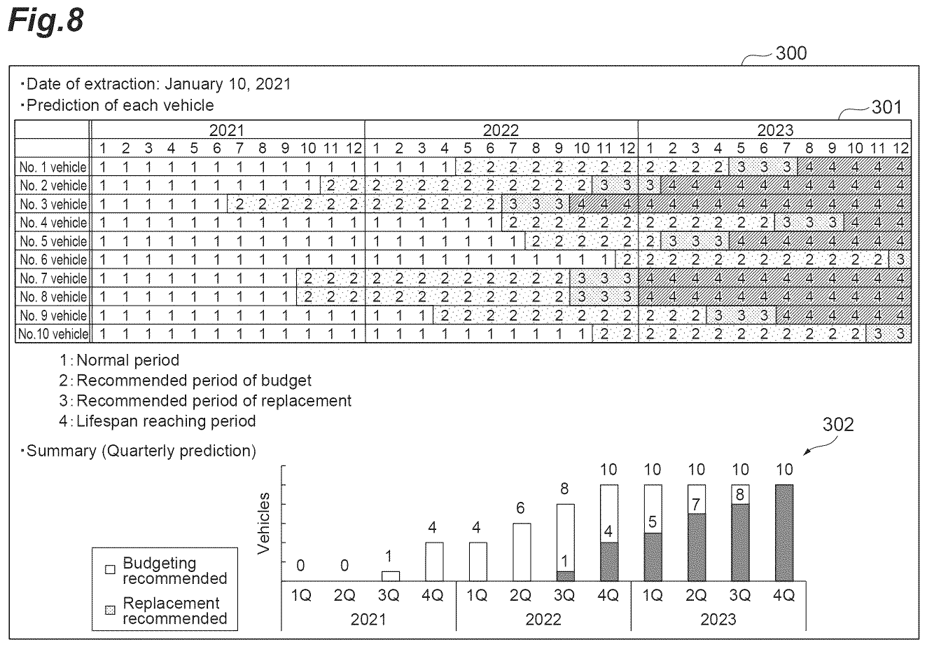

FIG. 8 is a diagram showing an example of the report. A report 300 in this example includes a time series heat map 301 indicating a temporal change in the future state of the rechargeable battery for each of the ten electric vehicle 2 and a bar graph 302 indicating the number of the electric vehicles 2 (rechargeable batteries) for which budgeting or replacement of rechargeable batteries is recommended.

The time series heat map 301 represents the temporal change for each rechargeable battery by four classifications: normal period (1); recommended period of budget (2); recommended period of replacement (3); and lifespan reaching period (4). For example, from the time series heat map 301, the following is expected for a rechargeable battery of a No. 1 vehicle. That is, until April 2022, the rechargeable battery is normally available. Budgeting for replacement is recommended between May 2022 and April 2023. Replacement of the rechargeable battery is recommended between May and July 2023. The rechargeable battery reaches its end of life in August 2023 or later.

The bar graph 302 indicates the number of the electric vehicles 2 for which budgeting is recommended and the number of the electric vehicles 2 for which replacement of the rechargeable battery is recommended, for each quarter. For example, from the bar graph 302, in the third quarter in 2022 (July to September in 2022), it is expected that budgeting is recommended for seven electric vehicles 2 and replacement of the rechargeable battery is recommended for one electric vehicle 2.

The report 300 allows the user to plan to replace the rechargeable batteries. For example, the user may appropriately make a budget for replacing the rechargeable batteries or may determine when to sell or purchase new rechargeable batteries.

### (Program)

A battery management program for causing a computer or computer system to function as the battery management system 5 or the server 50 includes a program code for causing the computer or computer system to function as the receiving unit 51, the acquisition unit 52, the lifespan prediction unit 53, the state prediction unit 54, the generation unit 55, and the transmission unit 56. The battery management program may be provided after being non-temporarily recorded in a tangible recording medium such as a CD-ROM, a DVD-ROM, or a semiconductor memory. Alternatively, the battery management program may be provided as a data signal superimposed on a carrier through a communication network. The provided battery management program may be stored in the auxiliary storage unit 103, for example. The processor 101 reads and executes the battery management program from the auxiliary storage unit 103 to implement the functional modules described above.

### [Effects]

As described above, a battery management system according to an aspect of the present disclosure includes: an acquisition unit configured to acquire reference data indicating a state of a rechargeable battery in a reference period and target data indicating a state of the rechargeable battery in a target period that is after the reference period; a characteristic calculation unit configured to calculate a characteristic value corresponding to a state of charge of the rechargeable battery in the reference period as a reference characteristic value based on the reference data, and calculate a characteristic value corresponding to a state of charge of the rechargeable battery in the target period as a target characteristic value based on the target data; and a ratio calculation unit configured to calculate a ratio indicating a relationship between the reference characteristic value and the target characteristic value, as a reference value for predicting a lifespan of the rechargeable battery.

A battery management method according to an aspect of the present disclosure is executed by a battery management system including at least one processor. The battery management method includes: acquiring reference data indicating a state of a rechargeable battery in a reference period and target data indicating a state of the rechargeable battery in a target period that is after the reference period; calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and calculating a ratio indicating a relationship between the reference characteristic value and the target characteristic value, as a reference value for predicting a lifespan of the rechargeable battery.

A battery management program according to an aspect of the present disclosure causes a computer to execute: acquiring reference data indicating a state of a rechargeable battery in a reference period and target data indicating a state of the rechargeable battery in a target period that is after the reference period; calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and calculating a ratio indicating a relationship between the reference characteristic value and the target characteristic value, as a reference value for predicting a lifespan of the rechargeable battery.

In such aspects, a degree of change in the characteristic value corresponding to the state of charge of the rechargeable battery over time from the reference period to the target period is obtained as the reference value. This reference value makes it possible to predict how the characteristics of the rechargeable battery will change further in the future. Therefore, it can be said that the reference value is an effective index for predicting a lifespan of the rechargeable battery.

In the battery management system according to another aspect, the state of the rechargeable battery indicated by each of the reference data and the target data may include at least a measured voltage and a measured current of the rechargeable battery. The characteristic calculation unit may be configured to: calculate, by a statistical approach, an I-V characteristic that is a relationship among the measured current, the measured voltage, and the state of charge in the reference period, based on the reference data, and acquire the reference characteristic value based on the I-V characteristic; and calculate, the statistical approach, the I-V characteristic in the target period based on the target data, and acquire the target characteristic value based on the I-V characteristic. By calculating the reference characteristic value and the target characteristic value using the statistical approach, these characteristic values can be accurately calculated from the measurement values of the rechargeable battery. As a result, an improvement in accuracy can be expected for both the reference value and the prediction of the lifespan of the rechargeable battery.

In the battery management system according to another aspect, the characteristic calculation unit may be configured to calculate the I-V characteristic by the statistical approach, such that a mean square error between a theoretical voltage of the rechargeable battery acquired by the I-V characteristic based on an equivalent circuit of the rechargeable battery and the measured voltage is minimized. According to this method, the reference characteristic value and the target characteristic value can be accurately calculated.

In the battery management system according to another aspect, the characteristic calculation unit may be configured to use a Marquardt method or a multivariate analysis as the statistical approach to calculate the I-V characteristic. By using these methods, the reference characteristic value and the target characteristic value can be calculated at high speed.

In the battery management system according to another aspect, the characteristic calculation unit may be configured to: calculate a moving average of the measured voltage and a moving average of the measured current based on the reference data, and calculate the I-V characteristic in the reference period based on these moving averages; and calculate a moving average of the measured voltage and a moving average of the measured current based on the target data, and calculate the I-V characteristic in the target period based on these moving averages. By introducing the moving average in this manner, it is possible to accurately calculate the characteristic value while suppressing the amount of data for calculating the characteristic value.

In a battery management system according to another aspect, the rechargeable battery may be mounted on an electric vehicle. In this case, it is possible to obtain an effective index for predicting the lifespan of a rechargeable battery mounted on the electric vehicle.

In the battery management system according to another aspect, the characteristic calculation unit may be configured to: use a threshold for distinguishing whether the electric vehicle is in an idling state to select, for each of the reference data and the target data, partial data in which a moving average of the measured current is equal to or greater than the threshold; calculate the reference characteristic value based on the selected partial data of the reference data; and calculate the target characteristic value based on the selected partial data of the target data. In a case where a voltage at a small current is used, an error in calculation of the characteristic value becomes large. Further, depending on a current sensor, an offset error due to temperature and a hysteresis error due to residual magnetism become large at the time of a small current, which increases an error in the calculation of the state of charge. By excluding records of small currents, these errors can be reduced or avoided, and the characteristic value can be calculated with high accuracy.

In the battery management system according to another aspect, the electric vehicle may be a material handling vehicle. In this case, it is possible to obtain an effective index for predicting the lifespan of a rechargeable battery mounted on the material handling vehicle.

In the battery management system according to another aspect, the characteristic calculation unit may be configured to calculate an OCV-SOC parameter obtained from a relationship between the state of charge and an open-circuit voltage of the rechargeable battery, as the characteristic value corresponding to the state of charge of the rechargeable battery. The present inventors have found that it is effective to focus on the relationship between the SOC and OCV in order to predict the lifespan of the rechargeable battery of a control system (e.g., an electric vehicle) that operates at a low discharge rate. By using the OCV-SOC parameter, a reference value for the prediction can be obtained.

In the battery management system according to another aspect, the characteristic calculation unit may be configured to calculate a slope of a linear equation indicating a relationship between the state of charge and the open-circuit voltage, as the OCV-SOC parameter. The slope significantly represents the degradation of the rechargeable battery. Accordingly, by using the slope as the OCV-SOC parameter, i.e., the characteristic value, a reference value for predicting the lifespan of a rechargeable battery of a control system (e.g., an electric vehicle) operating at a low discharge rate may be obtained.

In the battery management system according to another aspect, the characteristic calculation unit may be configured to: calculate an inverse number of the slope in the reference period as the reference characteristic value; and calculate an inverse number of the slope in the target period as the target characteristic value. The ratio calculation unit may be configured to calculate a ratio of the target characteristic value to the reference characteristic value as the reference value. By this approach, it is possible to obtain a reference value for predicting the lifespan of a rechargeable battery in a control system (e.g., an electric vehicle) operating at a low discharge rate.

In the battery management system according to another aspect, the characteristic calculation unit may be configured to calculate a DCR-SOC parameter obtained from a relationship between the state of charge and a DC resistance of the rechargeable battery, as the characteristic value corresponding to the state of charge of the rechargeable battery. The present inventors have found that it is effective to focus on a relationship between the SOC and DCR in order to predict the lifespan of the rechargeable battery of a control system (e.g., an electric vehicle) operating at a high discharge rate. By using the DCR-SOC parameter, a reference value for the prediction can be obtained.

In the battery management system according to another aspect, the characteristic calculation unit may be configured to calculate the DC resistance when the state of charge is 50%, as the DCR-SOC parameter. As the state of charge is lower, the DC resistance greatly changes according to a degree of deterioration of the rechargeable battery. On the other hand, in a case where the state of charge becomes too low, an actual operation of a control system (e.g., electric vehicle) may be hindered. Therefore, by focusing on the DC resistance when the state of charge is 50%, it is possible to obtain a reference value for predicting the lifespan of a rechargeable battery of a control system operating at a high discharge rate, without affecting the actual operation of the control system.

In the battery management system according to another aspect, the characteristic calculation unit may be configured to: calculate the DC resistance when the state of charge is 50% in the reference period, as the reference characteristic value; and calculate the DC resistance when the state of charge is 50% in the target period, as the target characteristic value. The ratio calculation unit may be configured to calculate a ratio of the target characteristic value to the reference characteristic value as the reference value. According to this method, a reference value for predicting the lifespan of a rechargeable battery of a control system (electric vehicle) operating at a high discharge rate may be obtained.

The battery management system may further include a lifespan prediction unit configured to predict a battery life that is a lifespan of the rechargeable battery, based on the reference value. In this case, the lifespan of the rechargeable battery can be predicted appropriately, for example, with high accuracy, based on the reference value.

The battery management system may further include a state prediction unit configured to predict a temporal change of the state of the rechargeable battery in the future, based on the battery life. With this configuration, the future state of the rechargeable battery can be predicted.

In the battery management system according to another aspect, the state prediction unit may be configured to predict the temporal change using a plurality of classifications. In this case, the future state of the rechargeable battery can be predicted in more detail by the plurality of classifications.

In a battery management system according to another aspect, the rechargeable battery may be a lead-acid battery. In this case, an effective index for predicting the lifespan of the lead-acid battery can be obtained.

### [Modifications]

The foregoing has been a detailed description based on various examples of the present disclosure. However, the present disclosure is not limited to the examples described above. Various modifications are possible without departing from the scope of the present disclosure.

The characteristic calculation unit (e.g., the calculation unit 12 or the lifespan prediction unit 53) may calculate the reference characteristic value and the target characteristic value by a method other than the statistical approach. For example, the characteristic calculation unit may calculate the characteristic values using a Kalman filter whenever the measurement data is obtained.

A computer or a device different from the servers 10, 50 may calculate the reference value. For example, each BMU 3 may calculate the reference value for a corresponding rechargeable battery. That is, the battery management system may be implemented in the BMU 3.

The BMU 3 may calculate moving averages of the measured voltage and the measured current, and transmit the rechargeable battery data indicating these moving averages to the database 20. Alternatively, the BMU 3 may transmit, to the database 20, only data of intervals in which the moving average of the measured current is greater than or equal to a given threshold. As in the above examples, the threshold may be a value for distinguishing whether the electric vehicle 2 is in an idling state. In these cases, data traffic between the BMU 3 and the database 20 may be reduced, and the processing load in the server 10 or the server 50 can be reduced.

The processing procedure of the method executed by at least one processor is not limited to the example in the above embodiment. For example, some of the above-described steps (processes) may be omitted, or the steps may be executed in a different order. Further, any two or more steps among the above-described steps may be combined, or part of the steps may be modified or deleted. Alternatively, other steps may be executed in addition to the above-described steps.

In a comparison of the magnitude relationship between two numerical values in the present disclosure, either of two criteria of “equal to or greater than” and “greater than” may be used, and either of two criteria of “equal to or less than” and “less than” may be used. Such selection of the reference does not change the technical significance of the process of comparing the magnitude relationship between the two numerical values.

In the present disclosure, “at least one processor executes a first process, executes a second process, . . . , executes an n-th process” or an expression corresponding thereto indicates a concept including a case where an execution subject (i.e., a processor) of n processes from the first process to the n-th process changes in the middle. That is, this expression indicates a concept including both a case where all the n processes are executed by the same processor and a case where the processor changes in an arbitrary policy among the n processes.

With respect to the various examples above, the following items are provided as further examples.

(Item 1) A battery management system comprising:
an acquisition unit configured to acquire reference data indicating a state of a rechargeable battery mounted on an electric vehicle in a reference period and target data indicating a state of the rechargeable battery in a target period that is after the reference period;
a characteristic calculation unit configured to calculate a characteristic value corresponding to a state of charge of the rechargeable battery in the reference period as a reference characteristic value based on the reference data, and calculate a characteristic value corresponding to a state of charge of the rechargeable battery in the target period as a target characteristic value based on the target data; and
a ratio calculation unit configured to calculate a ratio indicating a relationship between the reference characteristic value and the target characteristic value, as a reference value for predicting a lifespan of the rechargeable battery.
   (Item 2) The battery management system according to item 1, wherein
the state of the rechargeable battery indicated by each of the reference data and the target data includes at least a measured voltage and a measured current of the rechargeable battery, and
wherein the characteristic calculation unit is configured to:
   calculate, by a statistical approach, an I-V characteristic that is a relationship among the measured current, the measured voltage, and the state of charge in the reference period, based on the reference data, and acquire the reference characteristic value based on the I-V characteristic; and
   calculate, the statistical approach, the I-V characteristic in the target period based on the target data, and acquire the target characteristic value based on the I-V characteristic.
      (Item 3) The battery management system according to item 2, wherein the characteristic calculation unit is configured to calculate the I-V characteristic by the statistical approach, such that a mean square error between a theoretical voltage of the rechargeable battery acquired by the I-V characteristic based on an equivalent circuit of the rechargeable battery and the measured voltage is minimized.
      (Item 4) The battery management system according to item 3, wherein the characteristic calculation unit is configured to use a Marquardt method or a multivariate analysis as the statistical approach to calculate the I-V characteristic.
      (Item 5) The battery management system according to any one of items 2 to 4, wherein the characteristic calculation unit is configured to:
calculate a moving average of the measured voltage and a moving average of the measured current based on the reference data, and calculate the I-V characteristic in the reference period based on these moving averages; and
calculate a moving average of the measured voltage and a moving average of the measured current based on the target data, and calculate the I-V characteristic in the target period based on these moving averages. (Item 6) The battery management system according to any one of items 2 to 5, wherein the characteristic calculation unit is configured to:
use a threshold for distinguishing whether the electric vehicle is in an idling state to select, for each of the reference data and the target data, partial data in which a moving average of the measured current is equal to or greater than the threshold;
calculate the reference characteristic value based on the selected partial data of the reference data; and
   calculate the target characteristic value based on the selected partial data of the target data.
   (Item 7) The battery management system according to any one of items 1 to 6, wherein the characteristic calculation unit is configured to calculate an OCV-SOC parameter obtained from a relationship between the state of charge and an open-circuit voltage of the rechargeable battery, as the characteristic value corresponding to the state of charge of the rechargeable battery.
   (Item 8) The battery management system according to item 7, wherein the characteristic calculation unit is configured to calculate a slope of a linear equation indicating a relationship between the state of charge and the open-circuit voltage, as the OCV-SOC parameter.
   (Item 9) The battery management system according to item 8, wherein
the characteristic calculation unit is configured to:
   calculate an inverse number of the slope in the reference period as the reference characteristic value; and
   calculate an inverse number of the slope in the target period as the target characteristic value, and
the ratio calculation unit is configured to calculate a ratio of the target characteristic value to the reference characteristic value as the reference value.
   (Item 10) The battery management system according to any one of items 1 to 9, wherein the characteristic calculation unit is configured to calculate a DCR-SOC parameter obtained from a relationship between the state of charge and a DC resistance of the rechargeable battery, as the characteristic value corresponding to the state of charge of the rechargeable battery.
   (Item 11) The battery management system according to item 10, wherein the characteristic calculation unit is configured to calculate the DC resistance when the state of charge is 50%, as the DCR-SOC parameter.
   (Item 12) The battery management system according to item 11, wherein
the characteristic calculation unit is configured to:
   calculate the DC resistance when the state of charge is 50% in the reference period, as the reference characteristic value; and
   calculate the DC resistance when the state of charge is 50% in the target period, as the target characteristic value, and
the ratio calculation unit is configured to calculate a ratio of the target characteristic value to the reference characteristic value as the reference value.
   (Item 13) The battery management system according to any one of items 1 to 12, further comprising a prediction unit configured to predict a lifespan of the rechargeable battery, based on the reference value.
   (Item 14) The battery management system according to any one of items 1 to 13, wherein the electric vehicle is a material handling vehicle.
   (Item 15) The battery management system according to any one of items 1 to 14, wherein the rechargeable battery is a lead-acid battery.
   (Item 16) A battery management method executed by a battery management system comprising at least one processor, the method comprising:
acquiring reference data indicating a state of a rechargeable battery in a reference period and target data indicating a state of the rechargeable battery mounted on an electric vehicle in a target period that is after the reference period;
calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and
calculating a ratio indicating a relationship between the reference characteristic value and the target characteristic value, as a reference value for predicting a lifespan of the rechargeable battery.
   (Item 17) A battery management program causing a computer to execute:
acquiring reference data indicating a state of a rechargeable battery in a reference period and target data indicating a state of the rechargeable battery mounted on an electric vehicle in a target period that is after the reference period;
calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and
calculating a ratio indicating a relationship between the reference characteristic value and the target characteristic value, as a reference value for predicting a lifespan of the rechargeable battery.
   (Item 18) A battery management system comprising:
an acquisition unit configured to acquire rechargeable battery data indicating a state of a rechargeable battery mounted on an electric vehicle;
a lifespan prediction unit configured to predict a battery life that is a lifespan of the rechargeable battery, based on the rechargeable battery data; and
a state prediction unit configured to predict a temporal change of a state of the rechargeable battery in the future based on the battery life; and
a generation unit configured to generate a report indicating the temporal change; and
an output unit configured to output the report.
   (Item 19) The battery management system according to item 18, wherein
the state prediction unit is configured to predict the temporal change using a plurality of classifications, and
the generation unit is configured to generate the report representing the temporal change using the plurality of classifications.
   (Item 20) The battery management system according to item 19, wherein the plurality of classifications includes a first classification representing a period in which budgeting for replacing the rechargeable battery is recommended.
   (Item 21) The battery management system according to item 20, wherein the plurality of classifications further includes at least one of a second classification representing a period in which the rechargeable battery can be normally used, a third classification indicating a period in which replacement of the rechargeable battery is recommended, and a fourth classification indicating a period in which the lifespan of the rechargeable battery expires.
   (Item 22) The battery management system according to any one of items 18 to 21, wherein
the lifespan prediction unit is configured to:
   acquire reference data indicating a state of the rechargeable battery in a reference period and target data indicating a state of the rechargeable battery in a target period that is after the reference period;
   calculate a characteristic value corresponding to a state of charge of the rechargeable battery in the reference period, as a reference characteristic value, based on the reference data;
   calculate a characteristic value corresponding to a state of charge of the rechargeable battery in the target period, as a target characteristic value, based on the target data;
   calculate a ratio indicating a relationship between the reference characteristic value and the target characteristic value as a reference value; and
   predict the battery life based on the reference value.
      (Item 23) The battery management system according to any one of items 18 to 22, wherein the electric vehicle is a material handling vehicle.
      (Item 24) The battery management system according to any one of items 18 to 23, wherein the rechargeable battery is a lead-acid battery.
      (Item 25) A battery management method executed by a battery management system comprising at least one processor, the method comprising:
acquiring rechargeable battery data indicating a state of a rechargeable battery mounted on an electric vehicle;
predicting a battery life that is a lifespan of the rechargeable battery, based on the rechargeable battery data; and
predicting a temporal change of a state of the rechargeable battery in the future based on the battery life; and
generating a report indicating the temporal change; and
outputting the report.
   (Item 26) A battery management program causing a computer to execute:
acquiring rechargeable battery data indicating a state of a rechargeable battery mounted on an electric vehicle;
predicting a battery life that is a lifespan of the rechargeable battery, based on the rechargeable battery data; and
predicting a temporal change of a state of the rechargeable battery in the future based on the battery life; and
generating a report indicating the temporal change; and
outputting the report.

According to item 1, item 16, or item 17, a degree of change in the characteristic value corresponding to the state of charge of the rechargeable battery over time from the reference period to the target period is obtained as the reference value. This reference value makes it possible to predict how the characteristics of the rechargeable battery will change further in the future. Therefore, it can be said that the reference value is an effective index for predicting the lifespan of a rechargeable battery.

According to Item 2, by calculating the reference characteristic value and the target characteristic value using the statistical approach, these characteristic values can be accurately calculated from the measurement values of the rechargeable battery. As a result, an improvement in accuracy can be expected for both the reference value and the prediction of the lifespan of the rechargeable battery.
According to item 3, the reference characteristic value and the target characteristic value can be calculated with high accuracy.
According to Item 4, the reference characteristic value and the target characteristic value can be calculated at high speed.
According to Item 5, by introducing the moving average, it is possible to accurately calculate the characteristic value while suppressing the amount of data for calculating the characteristic value.
With regard to item 6, the use of a voltage at a low current results in a large error in the calculation of the characteristic value. Further, depending on a current sensor, an offset error due to temperature and a hysteresis error due to residual magnetism become large at the time of a small current, which increases an error in the calculation of the state of charge. According to item 6, by excluding records of small currents, those errors can be reduced or avoided, and characteristic values can be calculated with high accuracy.
Regarding item 7, the present inventors have found that it is effective to focus on a relationship between the SOC and OCV in order to predict the lifespan of the rechargeable battery of an electric vehicle operating at a low discharge rate. By using the OCV-SOC parameter, a reference value for the prediction can be obtained.
In item 8, the slope of the linear equation significantly indicates degradation of the rechargeable battery. Therefore, by using the slope as the OCV-SOC parameter, i.e., the characteristic value, it is possible to obtain a reference value for predicting the lifespan of a rechargeable battery of an electric vehicle operating at a low discharge rate.
According to item 9, it is possible to obtain a reference value for predicting the lifespan of a rechargeable battery of an electric vehicle operating at a low discharge rate.
Regarding item 10, the present inventors have found that it is effective to focus on a relationship between the SOC and DCR in order to predict the lifespan of the rechargeable battery of an electric vehicle operating at a high discharge rate. By using the DCR-SOC parameter, a reference value for the prediction can be obtained.
Regarding item 11, the lower the state of charge is, the more the DC resistance changes depending on a degree of deterioration of the rechargeable battery. On the other hand, in a case where the state of charge becomes too low, an actual operation of the electric vehicle may be hindered. Therefore, by focusing on the DC resistance when the state of charge is 50%, it is possible to obtain a reference value for predicting the lifespan of a rechargeable battery of an electric vehicle operating at a high discharge rate, without affecting the actual operation of the electric vehicle.
According to item 12, it is possible to obtain a reference value for predicting the lifespan of a rechargeable battery of an electric vehicle operating at a high discharge rate.
According to Item 13, it is possible to appropriately predict the lifespan of the rechargeable battery based on the reference value, for example, with high accuracy.
According to Item 14, it is possible to obtain an effective index for predicting the lifespan of a rechargeable battery mounted on a material handling vehicle.
According to Item 15, it is possible to obtain an effective index for predicting the lifespan of a lead-acid battery mounted on an electric vehicle.
According to item 18, item 25, or item 26, the battery life of the rechargeable battery mounted on the electric vehicle is predicted. Then, the report indicating a transition of the state of the rechargeable battery in the future is generated based on the battery life. By this report, the future state of the rechargeable battery mounted on the electric vehicle can be transmitted to the user.
According to Item 19, the temporal change in the state of the rechargeable battery can be indicated to the user in an easy-to-understand manner, by the plurality of classifications.
According to the item 20, it is possible to easily procure the cost necessary for replacing the rechargeable battery.
According to the item 21, the temporal change of the state of the rechargeable battery can be shown in detail to the user.
According to item 22, a degree of change in the characteristic value corresponding to the state of charge of the rechargeable battery over time from the reference period to the target period is obtained as the reference value, and the battery life is predicted by the reference value. Since the battery life is appropriately predicted by this method, a useful report can be provided to the user. For example, since the battery life is accurately predicted, an improvement in accuracy can be expected for the temporal change of the state of the rechargeable battery indicated by the report.
According to the item 23, the future state of the rechargeable battery mounted on the material handling vehicle can be transmitted to the user.
According to item 24, the future state of the lead-acid battery mounted on the electric vehicle can be transmitted to the user.

### REFERENCE SIGNS LIST

1 . . . battery management system, 2 . . . electric vehicle, 3 . . . BMU, 10 . . . server, 11 . . . acquisition unit, 12 . . . calculation unit, 13 . . . output unit, 20 . . . database, 30 . . . user terminal, 50 . . . server, 51 . . . receiving unit, 52 . . . acquisition unit, 53 . . . lifespan prediction unit, 54 . . . state prediction unit, 55 . . . generation unit, 56 . . . transmission unit, 20 . . . database, 300 . . . report.

1. A battery management system comprising:
an acquisition unit configured to acquire reference data indicating a state of a rechargeable battery in a reference period and target data indicating a state of the rechargeable battery in a target period that is after the reference period;
a characteristic calculation unit configured to calculate a characteristic value corresponding to a state of charge of the rechargeable battery in the reference period as a reference characteristic value based on the reference data, and calculate a characteristic value corresponding to a state of charge of the rechargeable battery in the target period as a target characteristic value based on the target data; and
a ratio calculation unit configured to calculate a ratio indicating a relationship between the reference characteristic value and the target characteristic value, as a reference value for predicting a lifespan of the rechargeable battery.

2. The battery management system according to claim 1, wherein
the state of the rechargeable battery indicated by each of the reference data and the target data includes at least a measured voltage and a measured current of the rechargeable battery, and
wherein the characteristic calculation unit is configured to:
calculate, by a statistical approach, an I-V characteristic that is a relationship among the measured current, the measured voltage, and the state of charge in the reference period, based on the reference data, and acquire the reference characteristic value based on the I-V characteristic; and
calculate, the statistical approach, the I-V characteristic in the target period based on the target data, and acquire the target characteristic value based on the I-V characteristic.

3. The battery management system according to claim 2, wherein the characteristic calculation unit is configured to calculate the I-V characteristic by the statistical approach, such that a mean square error between a theoretical voltage of the rechargeable battery acquired by the I-V characteristic based on an equivalent circuit of the rechargeable battery and the measured voltage is minimized.

4. The battery management system according to claim 3, wherein the characteristic calculation unit is configured to use a Marquardt method or a multivariate analysis as the statistical approach to calculate the I-V characteristic.

5. The battery management system according to claim 2 the characteristic calculation unit is configured to:
calculate a moving average of the measured voltage and a moving average of the measured current based on the reference data, and calculate the I-V characteristic in the reference period based on these moving averages; and
calculate a moving average of the measured voltage and a moving average of the measured current based on the target data, and calculate the I-V characteristic in the target period based on these moving averages.

6. The battery management system according to claim 2, wherein the rechargeable battery is mounted on an electric vehicle.

7. The battery management system according to claim 6, wherein the characteristic calculation unit is configured to:
use a threshold for distinguishing whether the electric vehicle is in an idling state to select, for each of the reference data and the target data, partial data in which a moving average of the measured current is equal to or greater than the threshold;
calculate the reference characteristic value based on the selected partial data of the reference data; and
calculate the target characteristic value based on the selected partial data of the target data.

8. The battery management system according to claim 6, wherein
the electric vehicle is a material handling vehicle.

9. The battery management system according to claim 1, wherein the characteristic calculation unit is configured to calculate an OCV-SOC parameter obtained from a relationship between the state of charge and an open-circuit voltage of the rechargeable battery, as the characteristic value corresponding to the state of charge of the rechargeable battery.

10. The battery management system according to claim 9, wherein the characteristic calculation unit is configured to calculate a slope of a linear equation indicating a relationship between the state of charge and the open-circuit voltage, as the OCV-SOC parameter.

11. The battery management system according to claim 10, wherein
the characteristic calculation unit is configured to:
calculate an inverse number of the slope in the reference period as the reference characteristic value; and
calculate an inverse number of the slope in the target period as the target characteristic value, and
the ratio calculation unit is configured to calculate a ratio of the target characteristic value to the reference characteristic value as the reference value.

12. The battery management system according to claim 1, wherein the characteristic calculation unit is configured to calculate a DCR-SOC parameter obtained from a relationship between the state of charge and a DC resistance of the rechargeable battery, as the characteristic value corresponding to the state of charge of the rechargeable battery.

13. The battery management system according to claim 12, wherein the characteristic calculation unit is configured to calculate the DC resistance when the state of charge is 50%, as the DCR-SOC parameter.

14. The battery management system according to claim 13, wherein
the characteristic calculation unit is configured to:
calculate the DC resistance when the state of charge is 50% in the reference period, as the reference characteristic value; and
calculate the DC resistance when the state of charge is 50% in the target period, as the target characteristic value, and
the ratio calculation unit is configured to calculate a ratio of the target characteristic value to the reference characteristic value as the reference value.

15. The battery management system according to claim 1, further comprising a lifespan prediction unit configured to predict a battery life that is a lifespan of the rechargeable battery, based on the reference value.

16. The battery management system according to claim 15, further comprising a state prediction unit configured to predict a temporal change of the state of the rechargeable battery in the future, based on the battery life.

17. The battery management system according to claim 16, wherein the state prediction unit is configured to predict the temporal change using a plurality of classifications.

18. The battery management system according to claim 1, wherein the rechargeable battery is a lead-acid battery.

19. A battery management method executed by a battery management system comprising at least one processor, the method comprising:
acquiring reference data indicating a state of a rechargeable battery in a reference period and target data indicating a state of the rechargeable battery in a target period that is after the reference period;
calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and
calculating a ratio indicating a relationship between the reference characteristic value and the target characteristic value, as a reference value for predicting a lifespan of the rechargeable battery.

20. A non-transitory computer-readable storage medium storing a battery management program causing a computer to execute:
acquiring reference data indicating a state of a rechargeable battery in a reference period and target data indicating a state of the rechargeable battery in a target period that is after the reference period;
calculating a characteristic value corresponding to a state of charge of the rechargeable battery in the reference period as a reference characteristic value based on the reference data, and calculating a characteristic value corresponding to a state of charge of the rechargeable battery in the target period as a target characteristic value based on the target data; and
calculating a ratio indicating a relationship between the reference characteristic value and the target characteristic value, as a reference value for predicting a lifespan of the rechargeable battery.
